(19) United States
(12) Patent Application Publication
(10) Pub. No.: US 2025/0365963 A1
(43) Pub. Date: Nov. 27, 2025

(54) SEMICONDUCTOR DEVICE

(71) Applicant: MACRONIX International Co., Ltd., Hsinchu (TW)

(72) Inventors: Hang-Ting Lue, Hsinchu County (TW); Pei-Ying Du, Hsinchu County (TW); Teng-Hao Yeh, Hsinchu County (TW); Wei-Chen Chen, Taoyuan City (TW)

(73) Assignee: MACRONIX International Co., Ltd., Hsinchu (TW)

(21) Appl. No.: 18/671,241

(22) Filed: May 22, 2024

(51) Int. Cl. H10B 43/35

(52) U.S. Cl. CPC H10B 43/35

(57) ABSTRACT

A semiconductor device includes a substrate, a well region, a transistor device, and a memory device. The substrate includes a first region and a second region. The well region is located in the first region and the second region of the substrate. The transistor device is located in the well region of the first region. The memory device is located in the well region of the second region. The well region is continuous between the transistor device and memory device.

### BACKGROUND

### Technical Field

The embodiments of the disclosure relate to an integrated circuit, and particularly, to a semiconductor device.

### Related Art

A non-volatile memory has the advantage that stored data does not disappear at power-off, so it becomes widely used for a personal computer or other electronic equipment. Recently, with the development of semiconductor technology, the size of electronic devices has been on the decrease, and the size of gate structures has also been on the decrease. However, as the size of the gate structure decreases, the current capable of passing through the channel below the gate structure decreases, and the performance of the device also decreases. To maintain or improve the performance of the device, the size of the device cannot be effectively reduced, so a larger area of the chip is occupied. Thus, how to reduce the occupied area and the overall process cost of the chip without reducing the performance of the device has become increasingly important.

### SUMMARY

The embodiments of the disclosure provide a semiconductor device capable of saving an occupied area of a chip and reducing the process cost.

An embodiment of the disclosure provides a semiconductor device including a substrate, a well region, a transistor device, and a memory device. The substrate includes a first region and a second region. The well region is located in the first region and the second region of the substrate. The transistor device is located in the well region of the first region. The memory device is located in the well region of the second region. The well region is continuous between the memory device and the transistor device.

Based on the above, in the embodiments of the disclosure, it is not required to dispose an isolation structure between the transistor device and the memory device, which reduces a distance between the transistor device and the memory device and thus saves an occupied chip area and reduce the overall process cost.

### BRIEF DESCRIPTION OF DRAWINGS

FIG. 1A to FIG. 1C are top views of a fabrication process of a semiconductor device according to a first embodiment of the disclosure.

FIG. 2A to FIG. 2H are cross-sectional views taken along a line A-A′ to a line H-H′ in FIG. 1C.

FIG. 3 is a top view of a semiconductor device according to a second embodiment of the

disclosure.

FIG. 4 is a cross-sectional view taken along a line A-A′ in FIG. 3.

### DESCRIPTION OF EMBODIMENTS

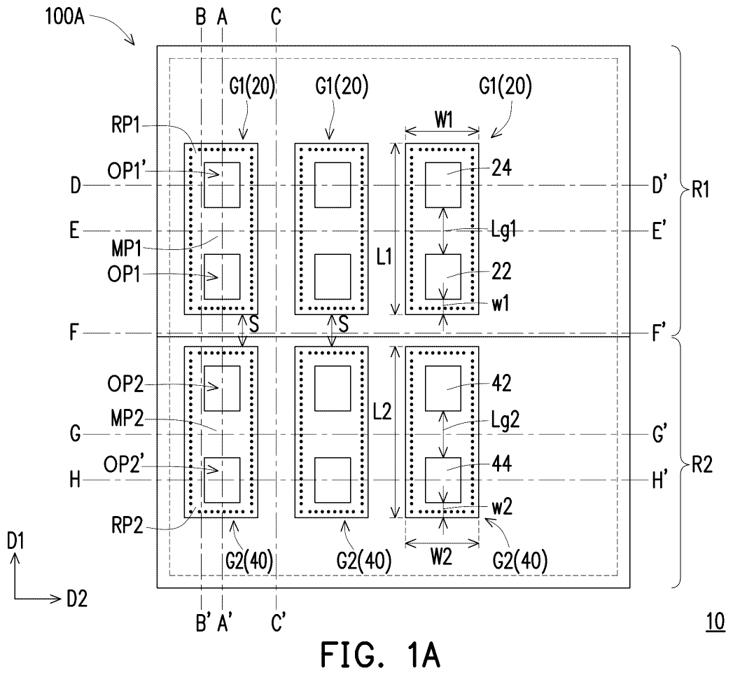

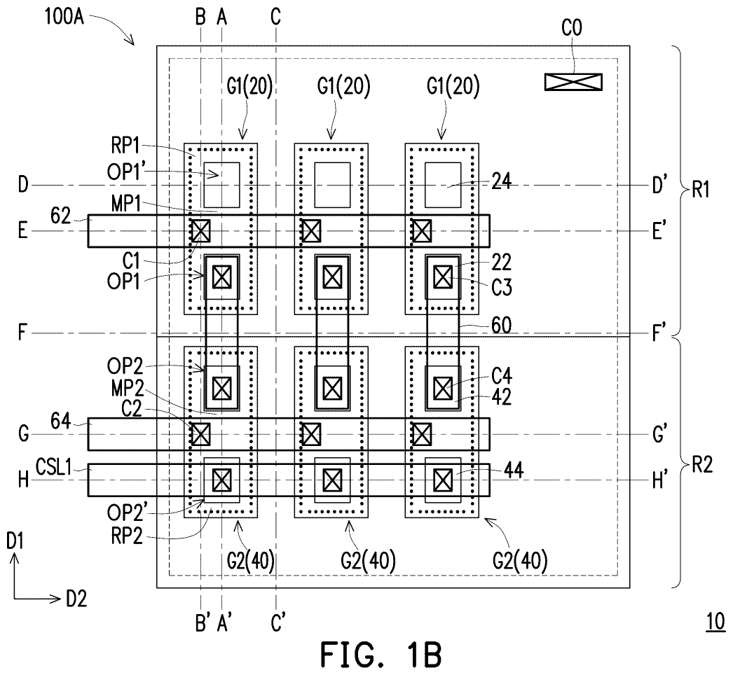

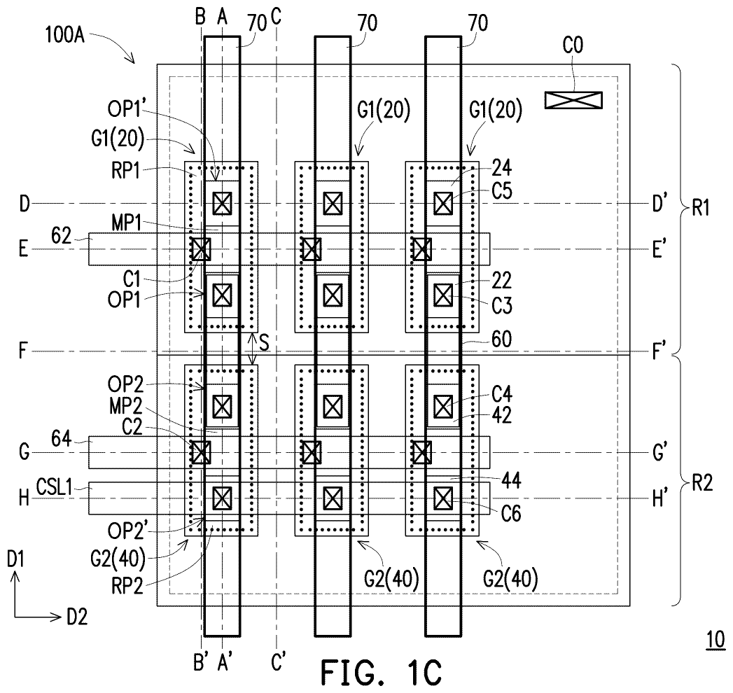

FIG. 1A to FIG. 1C are top views of a fabrication process of a semiconductor device

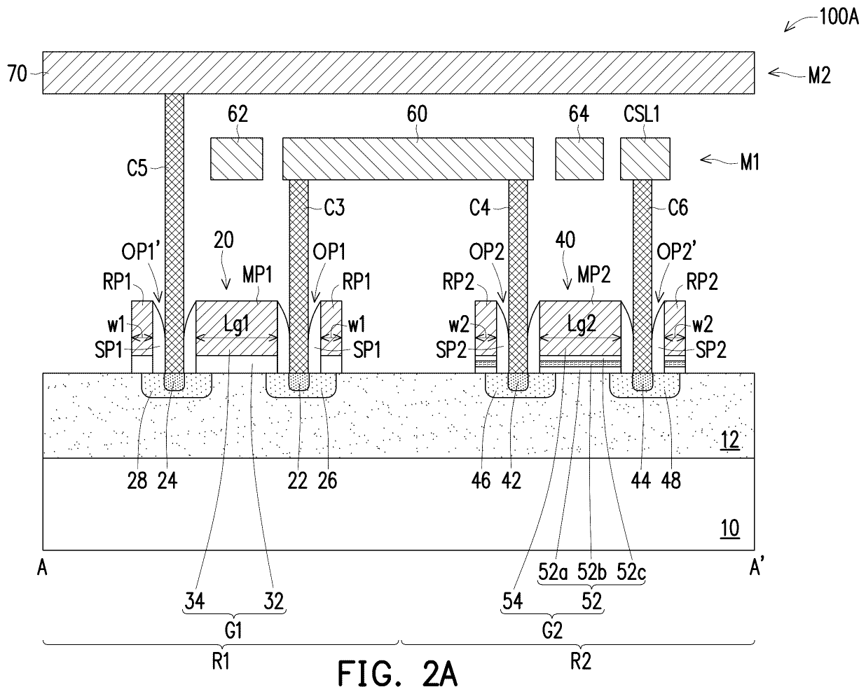

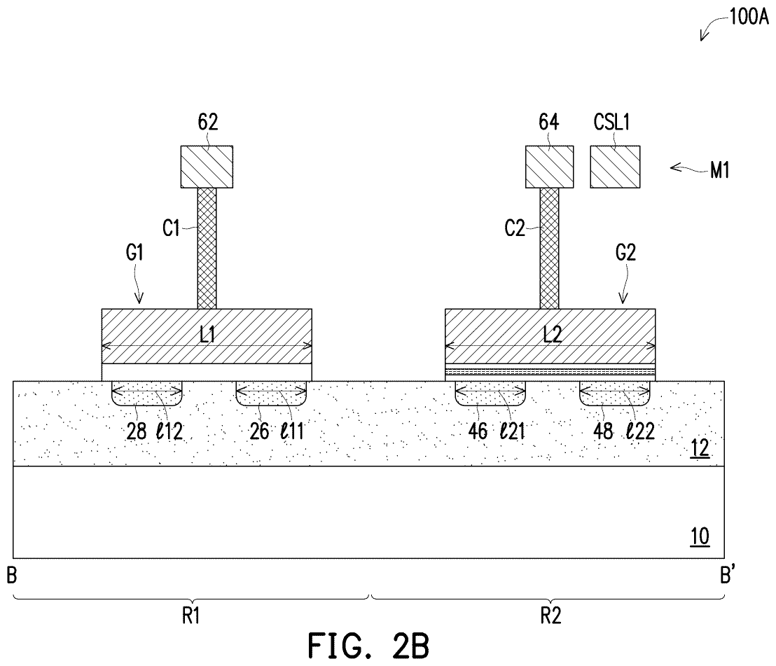

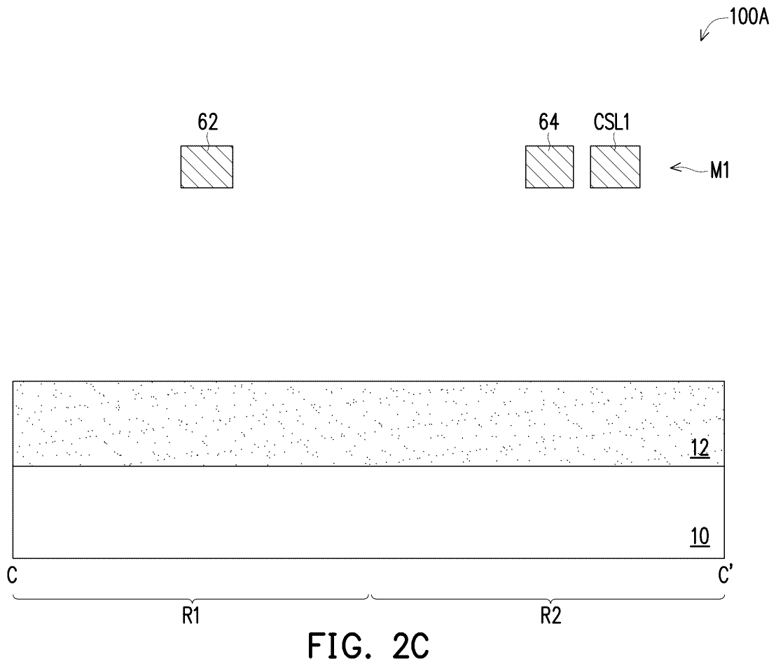

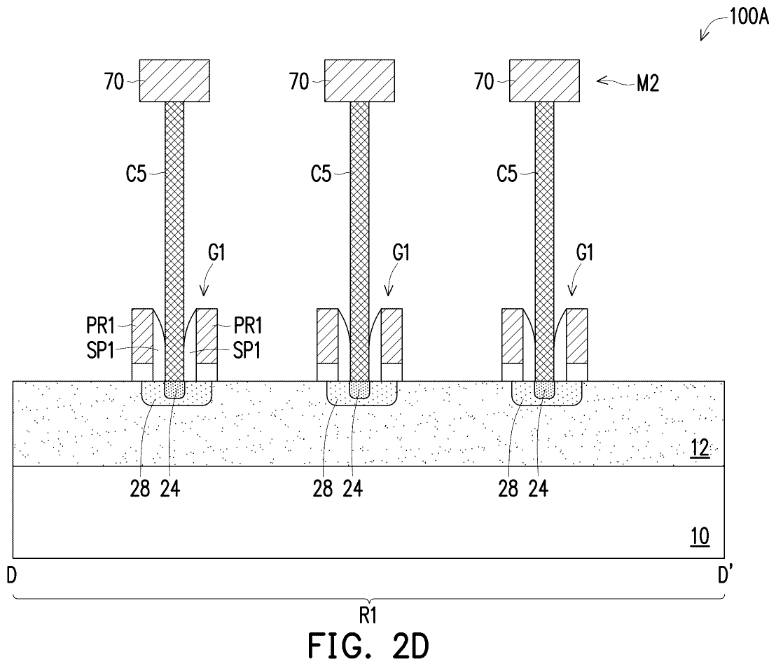

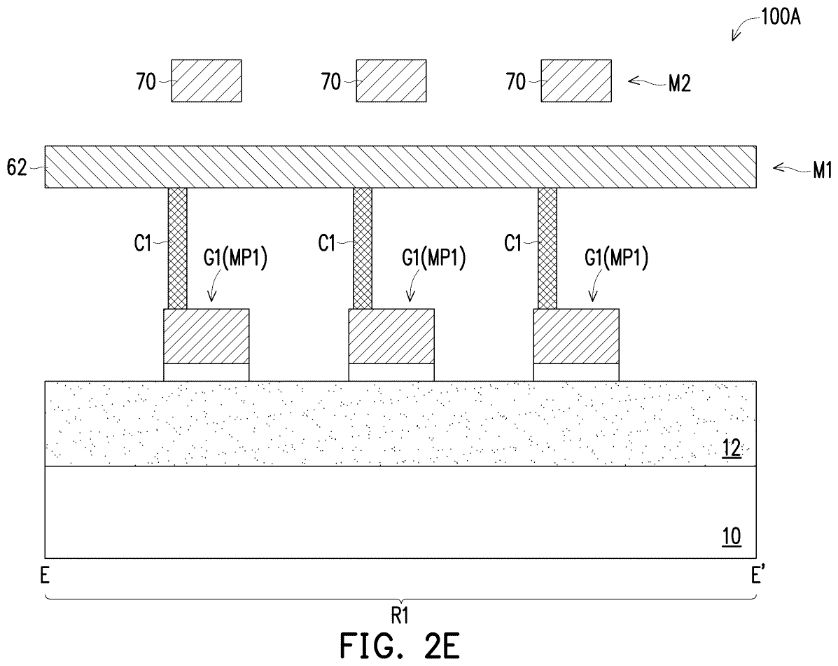

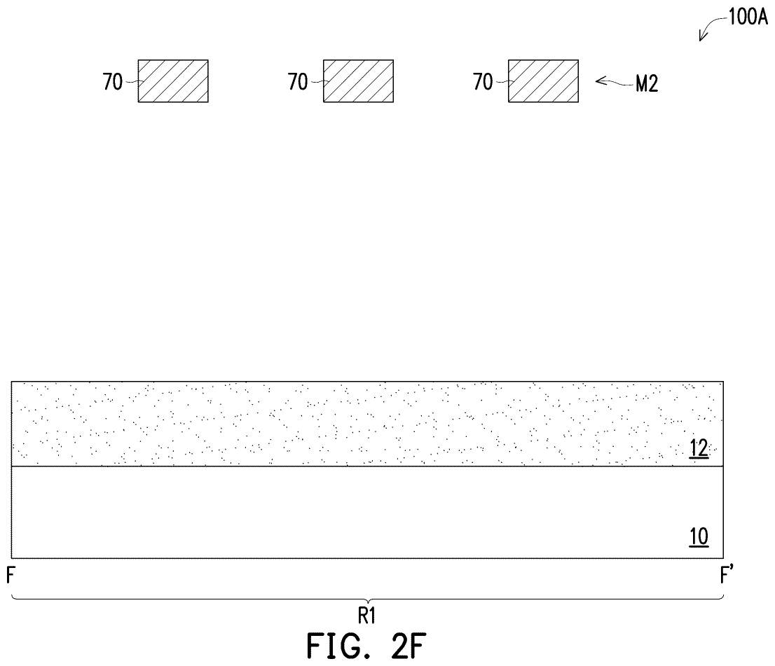

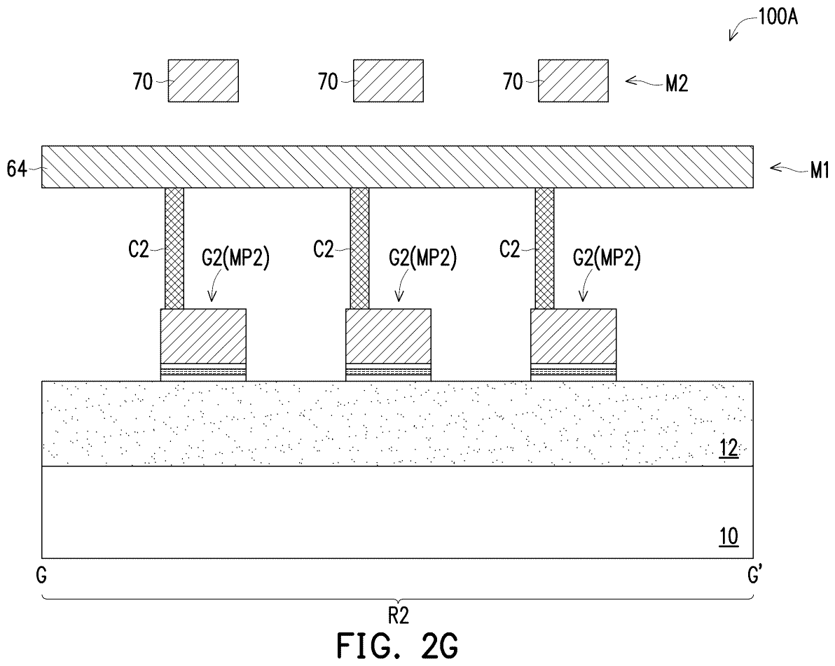

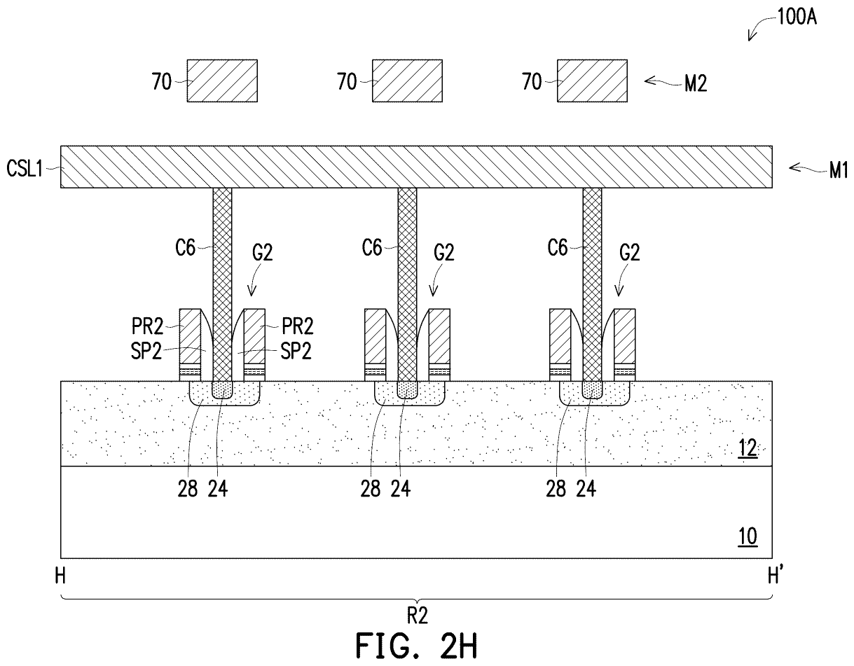

according to a first embodiment of the disclosure. FIG. 2A to FIG. 2H are cross-sectional views taken along a line A-A′ to a line H-H′ in FIG. 1C.

Referring to FIG. 1C and FIG. 2A, a semiconductor device 100A of the first embodiment of the disclosure includes a substrate 10, a well region 12, a plurality of transistor devices 20, and a plurality of memory devices 40.

Referring to FIG. 1A and FIG. 2A, the material of the substrate 10 includes a semiconductor such as silicon. In other alternative embodiments, the material of the substrate 10 includes a semiconductor compound such as germanium silicide, SiC, or other suitable Si-related materials. The substrate 10 includes a first region R1 and a second region R2. There is no isolation structure in the first region R1 and the second region R2. Also, there is no isolation structure between the first region R1 and the second region R2.

Referring to FIG. 1A and FIG. 2A, the well region 12 is located in the first region R1 and the second region R2 of the substrate 10. The well region 12 has, for example, a first conductivity type dopant. The first conductivity type dopant includes a P-type dopant such as boron or boron trifluoride. In one of the present embodiments, the well region 12 is a P-well region. In one of the present embodiments, the well region 12 is continuous between the first region R1 and the second region R2. In one of the present embodiments, a top surface of the well region 12 is continuous across the first region R1 and the second region R2.

Referring to FIG. 1A and FIG. 2A, the plurality of transistor devices 20 may serve as a plurality of select transistors. The plurality of transistor devices 20 are disposed in the well region 12 of the first region R1. In FIG. 1A, the plurality of transistor devices 20 are arranged in a row along a second direction D2. Each transistor device 20 includes a first gate structure G1, a first source/drain region 22, and a second source/drain region 24. The first gate structure G1 may include a gate dielectric layer 32 and a gate conductive layer 34. The gate dielectric layer 32 is, for example, silicon oxide, silicon nitride, or a high dielectric constant material. The gate conductive layer 34 is located on the gate dielectric layer 32. The gate conductive layer 34 is, for example, doped polysilicon, tungsten, metal silicide, or a combination thereof.

Referring to FIG. 1A and FIG. 2A, the plurality of memory devices 40 are disposed in the well region 12 of the second region R2. In FIG. 1A, the plurality of memory devices 40 are arranged in a row along the second direction D2. The plurality of memory devices 40 and the plurality of transistor devices 20 are disposed in a one-to-one correspondence with each other. In addition, FIG. 1A only shows three pairs of the memory devices 40 and the transistor devices 20. However, the disclosure is not limited thereto, and more pairs may be included along the second direction D2. There is no isolation structure in the well region 12 between the plurality of transistor devices 20 and the plurality of memory devices 40. In one of the present embodiments, a top surface of the well region 12 is continuous between the plurality of transistor devices 20 and the plurality of memory devices 40. In one of the present embodiments, a top surface of the well region 12 is continuous across the plurality of transistor devices 20 and the plurality of memory devices 40.

Each memory device 40 includes a second gate structure G2, a first source/drain region 42, and a second source/drain region 44. The second gate structure G2 may include a charge storage structure 52 and a gate conductive layer 54. The charge storage structure 52 includes a silicon oxide layer 52a, a silicon nitride layer 52b, and a silicon oxide layer 52c. The gate conductive layer 54 is located on the charge storage structure 52. The gate conductive layer 54 is, for example, doped polysilicon, tungsten, metal silicide, or a combination thereof. In one of the embodiments, the charge storage structure 52 includes other type of storage layer. For example, the silicon nitride layer 52 is instead of a floating gate layer.

Referring to FIG. 1A, in the embodiment of the disclosure, the first gate structure G1 and the second gate structure G2 extend along a first direction D1 and are aligned in a column along the first direction D1. In the top view, a periphery of the first gate structure G1 of the transistor device 20 is in a rectangular shape having a length L1 and a width W1. A periphery of the second gate structure G2 of the memory device 40 is in a rectangular shape having a length L2 and a width W2. In the top view, the first gate structure G1 and the second gate structure G2 have a contour of Arabic numeral “8”. The first gate structure G1 has openings OP1 and OP1′. The second gate structure G2 has openings OP2 and OP2′. The openings OP1, OP1′, OP2, and OP2′ extend and are aligned in a column along the first direction D1.

Referring to FIG. 1A, from another view point, the first gate structure G1 includes a middle part MP1 and a peripheral part RP1. The middle part MPI is located between the openings OP1 and OP1′. The openings OP1 and OP1′ are surrounded by the middle part MP1 and the peripheral part RP1. The middle part MPI defines a gate length Lg1. A width w1 of the peripheral part RP1 is, for example, greater than 0.1 μm. Similarly, the second gate structure G2 includes a middle part MP2 and a peripheral part RP2. The middle part MP2 is located between the openings OP2 and OP2′. The openings OP2 and OP2′ are surrounded by the middle part MP2 and the peripheral part RP2. The middle part MP2 defines a gate length Lg2. A width w2 of the peripheral part RP2 is, for example, greater than 0.1 μm. A distance S between the first gate structure G1 and the second gate structure G2 is, for example, between 0.18 μm and 0.28 μm. In one of the other embodiments, the distance S is depending on the space limitation of in different process nodes.

Referring to FIG. 1A and FIG. 2A, the first source/drain region 22 and the second source/drain region 24 of the transistor device 20 are respectively disposed in the well region 12 below the openings OP1 and OP1′. In some embodiments, the transistor device 20 further includes a first lightly doped source/drain region 26 and a second lightly doped source/drain region 28, which are respectively disposed around the first source/drain region 22 and the second source/drain region 24, such that the first source/drain region 22 and the second source/drain region 24 are respectively located within the first lightly doped source/drain region 26 and the second lightly doped source/drain region 28. Similarly, the first source/drain region 42 and the second source/drain region 44 of the memory device 40 are respectively disposed in the well region 12 below the openings OP2 and OP2′. In some embodiments, the memory device 40 further includes a first lightly doped source/drain region 46 and a second lightly doped source/drain region 48, which are respectively disposed around the first source/drain region 42 and the second source/drain region 44, such that the first source/drain region 42 and the second source/drain region 44 are respectively located within the first lightly doped source/drain region 46 and the second lightly doped source/drain region 48.

Referring to FIG. 2A and FIG. 2B, a portion of the first lightly doped source/drain region 26 and a portion of the second lightly doped source/drain region 28 are covered by the first gate structure G1. A portion of the first lightly doped source/drain region 46 and a portion of the second lightly doped source/drain region 48 are covered by the second gate structure G2. In some embodiments, the length L1 of the first gate structure G1 is greater than a sum of a length [symbol] 11 of the first lightly doped source/drain region 26 and a length [symbol] 12 of the second lightly doped source/drain region 28. The length L2 of the second gate structure G2 is greater than a sum of a length [symbol] 21 of the first lightly doped source/drain region 46 and a length [symbol] 22 of the second lightly doped source/drain region 48. That is, L1> [symbol] 11+ [symbol] 12, and L2> [symbol] 21+ [symbol] 22.

Referring to FIG. 2A, in some embodiments, the transistor device 20 further includes a plurality of spacers SP1. The spacers SP1 are located in the openings OP1 and OP1′. The spacers SP1 are located on sidewalls of the first gate structure G1 and are covered on the first lightly doped source/drain region 26 and the second lightly doped source/drain region 28. Similarly, the memory device 40 further includes a plurality of spacers SP2. The spacers SP2 are located in the openings OP2 and OP2′. The spacers SP2 are located on sidewalls of the second gate structure G2 and are covered on the first lightly doped source/drain region 46 and the second lightly doped source/drain region 48.

Referring to FIG. 1B, the first gate structures G1 are connected with a first conductive line 62. The second gate structures G2 are connected with a second conductive line 64. The first conductive line 62 and the second conductive line 64 respectively extend along the second direction D2 and are arranged side by side along the first direction D1. The second direction D2 is perpendicular to the first direction D1. Referring to FIG. 1B, FIG. 2B, and FIG. 2E, the first gate structure G1 is connected to the first conductive line 62 via a contact C1. Referring to FIG. 1B, FIG. 2B, and FIG. 2G, the second gate structure G2 is connected to the second conductive line 64 via a contact C2. The contacts C1 and C2 respectively land on the middle part MP1 of the first gate structure G1 and the middle part MP2 of the second gate structure G2. The contacts C1 and C2 may be arranged in a column along the first direction D1. The plurality of contacts C1 and the plurality of contacts C2 may be respectively arranged in rows along the second direction D2, as shown in FIG. 1B, FIG. 2E, and FIG. 2G.

Referring to FIG. 1B and FIG. 2A, the first source/drain region 22 of the transistor device 20 and the first source/drain region 42 of the memory device 40 are electrically connected to each other via a connection line 60. A plurality of connection lines 60 extend along the first direction D1 and are arranged side by side along the second direction D2. The plurality of connection lines 60 are disposed between the first conductive line 62 and the second conductive line 64.

Referring to FIG. 1B and FIG. 2A, the connection line 60 is connected to the first source/drain region 22 via a contact C3, and is connected to the first source/drain region 42 via a contact C4. The contact C3 passes through the opening OP1 and lands on the first source/drain region 22. The contact C4 passes through the opening OP2 and lands on the first source/drain region 42.

Referring to FIG. 1C and FIG. 2A, in this embodiment, the second source/drain region 44 of the memory device 40 is connected with a common source line CSL1, and the second source/drain region 24 of the transistor device 20 is connected with a third conductive line 70.

The common source line CSL1 extends along the second direction D2 and is arranged side by side with the first conductive line 62 and the second conductive line 64 along the first direction D1. The third conductive line 70 is disposed above the connection line 60, the first conductive line 62, and the second conductive line 64, and extends along the first direction D1. The first conductive line 62, the second conductive line 64, the common source line CSL1, and the connection line 60 are located in a first conductive layer M1, the third conductive line 70 is located in a second conductive layer M2, and the second conductive layer M2 is located above the first conductive layer M1. The third conductive line 70 is disposed above the connection line 60 and overlaps with the connection line 60.

Referring to FIG. 2A, the common source line CSL1 is connected to the second source/drain region 44 of the memory device 40 via a contact C6. The third conductive line 70 is connected to the second source/drain region 24 of the transistor device 20 via a contact C5. The contact C6 passes through the opening OP2′ and lands on the second source/drain region 44. The contact C5 passes through the opening OP1′ and lands on the second source/drain region 24. In addition, the well region 12 may be connected to a contact C0, as shown in FIG. 1C.

Referring to FIG. 1B, FIG. 1C, FIG. 2D, and FIG. 2H, in the embodiment of the disclosure, the plurality of contacts C3, the plurality of contacts C4, the plurality of contacts C5, and the plurality of contacts C6 may be respectively arranged in rows along the second direction D2. The contacts C5, C3, C4, and C6 may be arranged in a column along the first direction D1. The contacts C5, C3, C4, and C6 are disposed in a column different from the contacts C1 and C2.

The contacts C0, C1, C2, C3, C4, C5, and C6 may each be formed of one segment or composed of a plurality of segments. For example, the contacts C0, C1, C2, C3, C4, and C6 may each be formed of one segment. The contact C5 may be composed of two or more segments (not shown). In one of the other embodiments, the contact C5 is composed of one upper segment electrically connect to the third conductive line 70, and one lower segment electrically connect to the second source/drain region 24 of the transistor device 20. The upper segment electrically is connected to the lower segment through an intermediate metal layer in the first conductive layer M1. The contacts C4 and C6 are surrounded by the charge storage structure 52, and the contacts C4 and C6 are separated from the charge storage structure 52 by the spacer SP2. The contacts C3 and C5 are surrounded by the gate dielectric layer 32, and the contacts C3 and C5 are separated from the gate dielectric layer 32 by the spacer SP1.

Referring to FIG. 1C, FIG. 2A, and FIG. 2F, in the embodiment of the disclosure, no isolation structure is disposed in the well region 12 between the transistor device 20 and the memory device 40. That is, there is no isolation structure in the well region 12 between the first gate structure G1 and the second gate structure G2. There is no isolation structure in the well region 12 between the first source/drain region 22 and the first source/drain region 42. There is no isolation structure in the well region 12 between the first lightly doped source/drain region 26 and the first lightly doped source/drain region 46. Referring to FIG. 1C and FIG. 2C to FIG. 2D, there is no isolation structure in the well region 12 between the first gate structures G1 of the transistor devices 20. Referring to FIG. 1C, FIG. 2G, and FIG. 2H, there is also no isolation structure in the well region 12 between the second gate structures G2 of the memory devices 40. Thus, the disclosure is capable of saving an occupied chip area. The first lightly doped source/drain region 26 and the first lightly doped source/drain region 46 are separated from each other, and the first source/drain region 22 and the first source/drain region 42 are also separated from each other. The top surface of the well region 12 is continuously between the transistor device 20 and the memory device 40, continuously between two adjacent transistor devices 20 along the second direction D2, and continuously between two adjacent memory devices 40 along the second direction D2. In the first embodiment described above, the second source/drain region 44 of the memory device 40 is connected to the common source line CSL1, and the second source/drain region 24 of the transistor device 20 is connected to the third conductive line 70. However, the disclosure is not limited thereto. As long as one of the second source/drain region 44 of the memory device 40 and the second source/drain region 24 of the transistor device 20 is connected to the common source line CSL1, and the other of the second source/drain region 44 of the memory device 40 and the second source/drain region 24 of the transistor device 20 is connected to the third conductive line 70, the configuration falls within the scope of the disclosure.

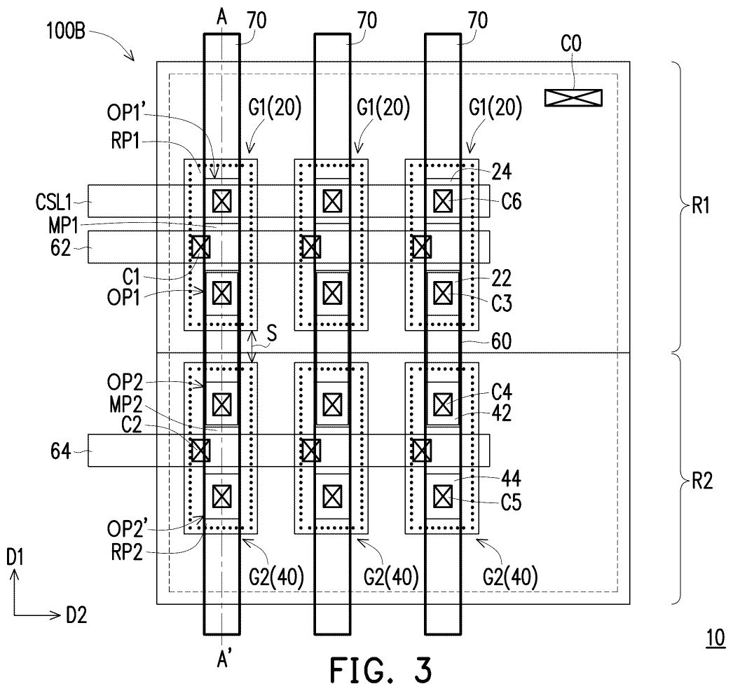

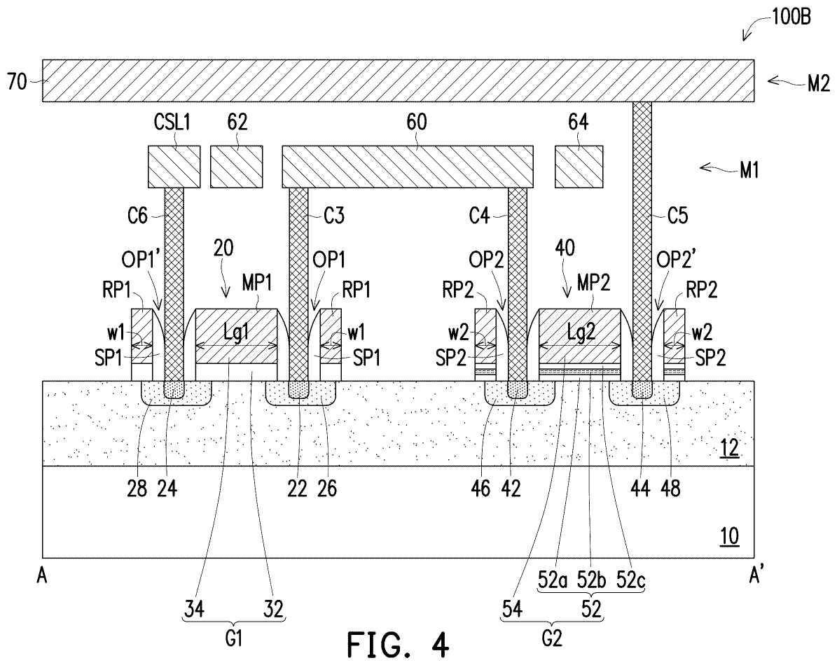

FIG. 3 is a top view of a semiconductor device according to a second embodiment of the disclosure. FIG. 4 is a cross-sectional view taken along a line A-A′ in FIG. 3.

Referring to FIG. 3 and FIG. 4, the second source/drain region 24 of the transistor device 20 is connected to the common source line CSL1, and the second source/drain region 44 of the memory device 40 is connected to the third conductive line 70. Similarly, in a semiconductor device 100B of the second embodiment of the disclosure, no isolation structure is disposed in the well region 12 between the transistor device 20 and the memory device 40. There is no isolation structure in the well region 12 between the first gate structures G1 of the transistor devices 20. Also, there is no isolation structure in the well region 12 between the second gate structures G2 of the memory devices 40. Thus, the disclosure is capable of saving an occupied chip area.

Based on the above, in the semiconductor device of the embodiments of the disclosure, it is not required to dispose an isolation structure between the transistor device and the memory device, so an occupied chip area can be reduced, and complexity of the fabrication process and fabrication costs can be lowered. In addition, since there is no isolation structure between the transistor device and the memory device, a double hump is not present in an electrical property curve of a gate voltage and a saturation current, and the structure can be more stable in the case of threshold voltage (Vt) mismatch. Thus, the embodiments of the disclosure are capable of exhibiting excellent subthreshold control of the CMOS to enable an ultra-low power design for a near-Vt subthreshold circuit.

What is claimed is:

1. A semiconductor device comprising:
a substrate comprising a first region and a second region;
a well region located in the first region and the second region of the substrate;
a transistor device located in the well region of the first region; and
a memory device located in the well region of the second region,
wherein the well region is continuous between the transistor device and the memory device.

2. The semiconductor device according to claim 1, wherein a first gate structure of the transistor device and a second gate structure of the memory device each comprise a middle part and a peripheral part, a first opening and a second opening are provided between the middle part and the peripheral part, and the middle part is located between the first opening and the second opening.

3. The semiconductor device according to claim 2, wherein there is no isolation structure in the well region between the transistor device and the memory device.

4. The semiconductor device according to claim 2, wherein the first gate structure and the second gate structure extend along a first direction and are aligned in a column along the first direction.

5. The semiconductor device according to claim 4, wherein the middle part of the first gate structure is connected to a first conductive line, the middle part of the second gate structure is connected to a second conductive line, and the first conductive line and the second conductive line respectively extend along a second direction and are arranged side by side along the first direction.

6. The semiconductor device according to claim 5, wherein a first source/drain region of the transistor device is located in the well region below the first opening of the first gate structure, and a first source/drain region of the memory device is located in the well region below the first opening of the second gate structure.

7. The semiconductor device according to claim 6, wherein the first opening of the first gate structure is adjacent to the first opening of the second gate structure.

8. The semiconductor device according to claim 7, wherein the first source/drain region of the transistor device is adjacent to and electrically connected to the first source/drain region of the memory device via a connection line.

9. The semiconductor device according to claim 8, wherein the connection line extends along the first direction and is disposed between the first conductive line and the second conductive line.

10. The semiconductor device according to claim 9, wherein a second source/drain region of the transistor device is located in the well region below the second opening of the first gate structure, and a second source/drain region of the memory device is located in the well region below the second opening of the second gate structure.

11. The semiconductor device according to claim 10, wherein one of the second source/drain region of the memory device and the second source/drain region of the transistor device is connected to a common source line, and the other of the second source/drain region of the memory device and the second source/drain region of the transistor device is connected to a third conductive line.

12. The semiconductor device according to claim 11, wherein the common source line extends along the second direction and is arranged side by side with the first conductive line and the second conductive line along the first direction.

13. The semiconductor device according to claim 11, wherein the third conductive line is disposed above the connection line, the first conductive line, and the second conductive line, and extends along the first direction.

14. The semiconductor device according to claim 11, wherein the first conductive line, the second conductive line, the common source line, and the connection line are located in a first conductive layer, the third conductive line is located in a second conductive layer, and the second conductive layer is located above the first conductive layer.

15. The semiconductor device according to claim 14, wherein the third conductive line overlaps with the connection line.

16. The semiconductor device according to claim 11, wherein the transistor device comprises a first lightly doped source/drain region and a second lightly doped source/drain region, which respectively surround the first source/drain region and the second source/drain region of the transistor device.

17. The semiconductor device according to claim 11, wherein the memory device comprises a first lightly doped source/drain region and a second lightly doped source/drain region, which respectively surround the first source/drain region and the second source/drain region of the memory device.

18. The semiconductor device according to claim 1, further comprising:
a plurality of contacts surrounded by the charge storage structure.

19. The semiconductor device according to claim 1, further comprising:
another transistor device located in the well region of the first region; and
another memory device located in the well region of the second region,
wherein the well region between the transistor device and the another transistor device is continuous, and the well between the memory device and the another memory device is continuous.

20. The semiconductor device according to claim 1, wherein a top surface of the well region continuously extends from the first region to the second region.
